(19) United States
(12) Patent Application Publication
(10) Pub. No.: US 2016/0353572 A1
(43) Pub. Date: Dec. 1, 2016

(54) PRINTED CIRCUIT BOARD, SEMICONDUCTOR PACKAGE AND METHOD OF MANUFACTURING THE SAME

(71) Applicant: SAMSUNG ELECTRO-MECHANICS CO., LTD., Suwon-si (KR)

(72) Inventors: Jae Hyun LIM, Suwon-si (KR); Jong Man KIM, Suwon-si (KR); Jin Su KIM, Suwon-si (KR); Heung Woo PARK, Suwon-si (KR); Sun Ho KIM, Suwon-si (KR); Jung Gon CHOI, Suwon-si (KR)

(73) Assignee: SAMSUNG ELECTRO-MECHANICS CO., LTD., Suwon-si (KR)

(21) Appl. No.: 15/016,136

(22) Filed: Feb. 4, 2016

(30) Foreign Application Priority Data
May 26, 2015 (KR) 10-2015-0073013

(51) Int. Cl. H05K 1/11; H05K 3/46; H05K 1/02

(52) U.S. Cl. CPC H05K 1/111; H05K 1/0298; H05K 1/115; H05K 3/4644; H05K 2201/09781

(57) ABSTRACT

A printed circuit board, a semiconductor package, and a method of producing the same are provided. The printed circuit board (PCB) includes an insulating layer and a circuit layer including metal pads exposed on a side surface and a lower surface of the insulating layer.

### CROSS-REFERENCE TO RELATED APPLICATION

This application claims the benefit under 35 USC 119(a) of Korean Patent Application No. 10-2015-0073013 filed on May 26, 2015, in the Korean Intellectual Property Office, the entire disclosure of which is incorporated herein by reference for all purposes.

### BACKGROUND

1. Field

The following description relates to a printed circuit board, a semiconductor package, and a method of manufacturing the same.

2. Description of Related Art

Cellular phones and other electronic devices used within the field of information technology (IT) are increasingly becoming multifunctional and becoming reduced in weight, thickness, length, and size. To produce these electronic devices, techniques for providing electronic components such as integrated chips (ICs), semiconductor chips, active elements, and passive elements therein have been developed. Further, recently, techniques for installing components on boards of such devices in various manners have been developed to increase the packing density of components within the devices.

A general printed circuit board (PCB) is an electrically insulating board on which, before electronic components are mounted, circuit line patterns are printed and formed with a conductive material such as copper. That is, a PCB is a circuit board on which the installation positions of components are defined and circuit patterns connecting the components are printed on a flat surface thereof in order to allow various types of electronic elements to be densely installed thereon.

A package mounted on such a PCB has a plurality of input/output (I/O) terminals therein to form circuit connections between components, and the plurality of I/O terminals may be connected through an interconnection method such as wire bonding or flipchip bonding.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a printed circuit board (PCB) includes an insulating layer and a circuit layer including metal pads exposed on a side surface and a lower surface of the insulating layer.

One of the metal pads may cover substantially the entire side surface of the insulating layer.

One of the metal pads may cover a portion of the side surface of the insulating layer.

The general aspect of the PCB may further include a solder resist layer having an opening exposing the metal pad.

The general aspect of the PCB may be a multilayer PCB.

The PCB may further include a via connecting an interlayer circuit layer, and the solder resist layer may be embedded in at least a portion of the via.

According to another general aspect, a method of manufacturing a semiconductor package may involve forming a circuit layer comprising a dummy via and a metal pad in an insulating layer, forming a solder resist layer having an opening exposing the metal pad to both surfaces of the insulating layer, and cutting through the dummy via to form a metal side surface pad of the insulating layer.

The insulating layer may be a built-up layer formed by stacking two or more layers.

The forming of the circuit layer may include the metal pad being formed on a lower surface of the dummy via.

In another general aspect, a method of manufacturing a semiconductor package involves obtaining a printed circuit board comprising an insulating layer and a metal side surface pad disposed on a side surface of the insulating layer, and mounting a semiconductor device on the printed circuit board.

The obtaining of the printed circuit board may involve: forming a metal lower surface pad on a surface of an insulating layer and forming a dummy via that penetrates the insulating layer; and cutting through the dummy via of the insulating layer to obtain the metal side surface pad on the side surface of the insulating layer.

The metal side surface pad and the metal lower surface pad may be formed adjacent to each other at a corner of the insulating layer.

In yet another general aspect, a method of manufacturing a semiconductor package system involves manufacturing a semiconductor package according to the method above, and electrically connecting the metal side surface pad of the semiconductor package with an external terminal of a main board by soldering.

The electrically connecting of the metal pad to the external terminal may involve soldering both the metal lower surface pad and the metal side surface pad to the external terminal.

Other features and aspects will be apparent from the following detailed description, the drawings, and the claims.

### BRIEF DESCRIPTION OF DRAWINGS

FIG. 1 is a cross-sectional view illustrating an example of a semiconductor package formed on a printed circuit board (PCB) according to the present description.

FIGS. 2 through 5 are cross-sectional views illustrating structures of various built-up layers of a PCB according to the example illustrated in FIG. 1.

FIG. 6 is a cross-sectional view schematically illustrating an example of a semiconductor package mounted on a main board.

FIG. 7 is a cross-sectional view illustrating a portion of the PCB of FIG. 6 soldered to the main board.

FIG. 8 is a view illustrating another example of a PCB according to the present description.

FIG. 9 is a view illustrating yet another example of a PCB according to the present description.

FIGS. 10 through 13 are cross-sectional views illustrating a sequential process of an example of a method for manufacturing a PCB according to FIG. 1.

FIGS. 14 through 18 are cross-sectional views illustrating a sequential process of an example of a method for manufacturing a PCB according to FIG. 8.

FIGS. 19 through 21 are cross-sectional views illustrating a sequential process of an example of a method for manufacturing a PCB according to FIG. 9.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that though the terms first, second, third, and the like may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing particular embodiments only and is not intended to be limiting of the present inventive concept. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, various examples will be described with reference to schematic drawings. In the drawings, for example, due to manufacturing techniques and/or tolerances, modifications of the shape shown may be estimated. Thus, examples should not be construed as being limited to the shapes of regions shown herein. The following embodiments may also be constituted by one or a combination thereof.

### Printed Circuit Board

First, an example of a PCB according to the present description will be described in detail. In this example, reference numerals not shown in the drawing referred to may be reference numerals present in other drawings denoting the same components.

FIG. 1 illustrates a cross-sectional view of an example of a semiconductor package formed on a printed circuit board (PCB).

Referring to FIG. 1, a semiconductor package according to this example includes a printed circuit board (PCB) 110 having an insulating layer 111, a circuit layer 112 including metal pads 112a and 112b exposed to both side surfaces and a lower surface of the insulating layer 111, and a solder resist layer 114 having openings exposing the metal pads 112a and 112b, and a semiconductor device 120 mounted on the PCB 110.

The insulating layer 111 of the PCB 110 is used as a base substrate, so it may be formed of a thermosetting insulating material, a ceramic, or an organic/inorganic composite material, or may be impregnated with a glass fiber, and when the insulating layer 111 includes a polymer resin, it may include an epoxy-based insulating resin such as FR-4, bismaleimide triazine (BT), or ajinomoto build-up film (ABF). Alternatively, the insulating layer 111 may include a polyimide-based resin, but the material of the insulating layer 111 is not limited thereto.

In this example, a via 113 penetrates through the insulating layer 111 in a thickness direction of the insulating layer 111. The via 113 is formed in the insulating layer 111 by using a YAG laser or a CO₂ laser. Circuit layers 112c are formed on upper and lower surfaces of the insulating layer 111, and the circuit layers 112c are electrically connected by the via 113.

The metal pads 112a and 112b are formed on both side surfaces of the insulating layer 111 and on a portion of the lower surface of the insulating layer 111. The metal pads 112a and 112b serve as bonding surfaces when a soldering process is subsequently performed on a main board.

In this example, the metal pads 112a formed on both side surfaces of the insulating layer 111 are formed by cutting the via formed in the insulating layer 111, and the metal pad 112b exposed to the lower surface of the insulating layer 111 is provided to be the same as that of the circuit layers 112c formed on upper and lower surfaces of the insulting layer 111.

The metal pads 112b and the circuit layers 112c formed on both surfaces of the insulating layer 111 may be formed through a subtractive method of selectively removing a metal material layer using corrosion resist after the metal material layer is stacked, an additive method using electroless copper plating and electro-copper plating, a semi-additive process (SAP) method, or a modified semi-additive process (MSAP) method. The detail descriptions thereof will be omitted as these methods are known to those skilled in the art.

The solder resist layer 114 serves to protect an external circuit layer such that solder is not coated on the external circuit layer when soldering is performed with a heat-resistant coating material. Also, for an electrical connection with an external circuit, an opening may be formed in the solder resist layer 114 to expose the metal pads 112a and 112b.

The semiconductor device 121 is mounted on the PCB and includes a molding part 122 molding the semiconductor device 121 to fix the semiconductor device 121. The molding part 122 encapsulates the semiconductor device 121 and a wire using a powder or pellet-type EMC in order to protect the semiconductor device 121 from external impacts and contaminants.

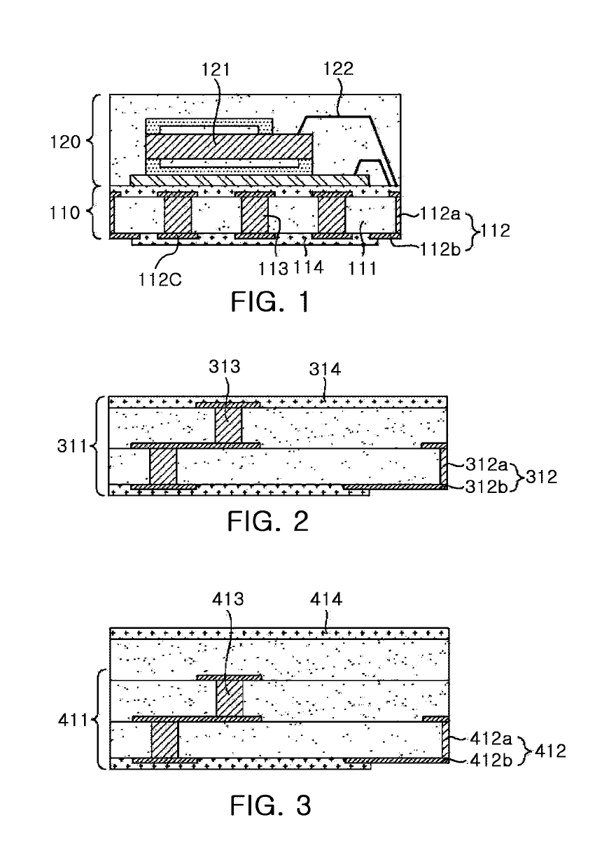

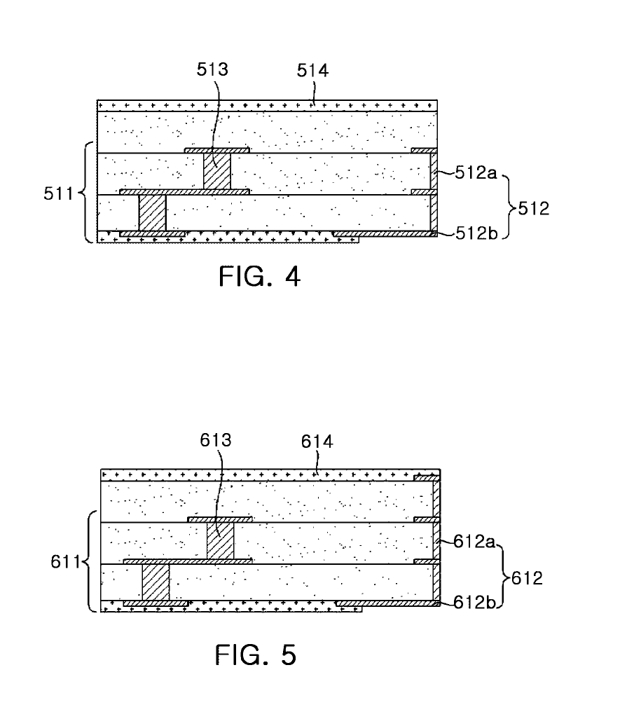

FIGS. 2 through 5 illustrate cross-sectional views of various built-up layers of a PCB applicable to the example illustrated in FIG. 1.

In the PCBs illustrated in FIGS. 2 through 5, additional built-up layers 311, 411, 511, and 611 extend the PCB illustrated in FIG. 1. That is, insulating layers and circuit layers may be further formed in the basic structure of 2 layers to extend in a manner of 2L→4L→6L→8L→10L and so on. The structure of the PCBs are not limited to having the illustrated built-up layers 311, 411, 511, and 611, and additional build-up layers may be formed as necessary.

Also, referring to FIGS. 2 through 5, solder resist layers 314, 414, 516, and 614 formed of a solder resist material are further provided on the outermost circuit layer, and an opening is provided on a lower surface of each of the built-up layers to expose a portion of each of the metal pads 312b, 412b, 512b, and 612b formed on the lower surface of each of the built-up layers 311, 411, 511, and 611.

Also, the metal pads 312a, 412a, 512a, and 612a may be formed on the entire side surface of the built-up layer of the PCB or on a portion of the side surface of the built-up layer. For example, in FIGS. 2 and 3, the metal pads 312a, 412a, and 512a are formed on portions of the side surfaces of the built-up layers, while in FIG. 5, the metal pad 612a is formed on the entire side surface of the built-up layer 611.

Vias 313, 413, 513, and 613 for connecting interlayer circuit layers are formed in the built-up layers 311, 411, 511, and 611 of the PCB.

In this example, repetitive descriptions in view of the example illustrated in FIG. 1 will be omitted.

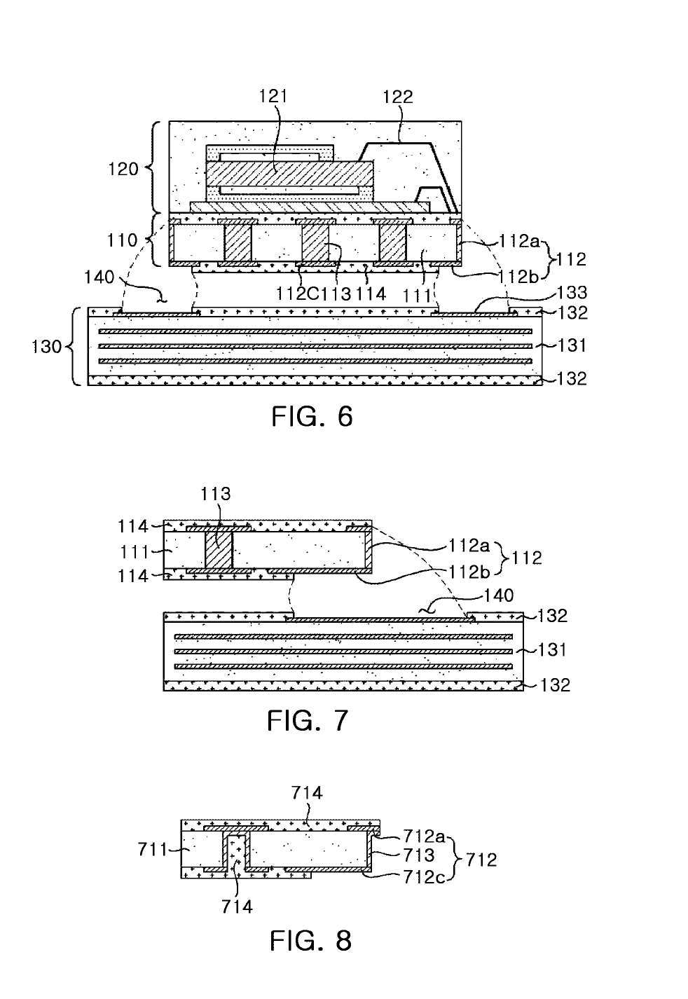

FIG. 6 schematically illustrates a cross-sectional view of an example of a semiconductor package system that is mounted on a main board, and FIG. 7 illustrates a portion of the PCB of FIG. 6 soldered to the main board.

The semiconductor package system illustrated in FIG. 6, which employs the PCB according to the example illustrated in FIG. 1, includes a PCB 110 having an insulating layer 111 and a circuit layer 112 including metal pads 112a and 112b exposed to both side surfaces and a lower surface of the insulating layer 111, a semiconductor package including a semiconductor device 120 mounted on the PCB 110, and a main board 130 on which the semiconductor package is mounted by establishing an electrical connection to an external connection terminal 140 of the PCB 110. The electrical connection may be obtained by a solder disposed between the external connection and the metal pads 112a and 112b.

In this example, the metal pads 112a and 112b formed on the lower surface and the side surface of the semiconductor package including the metal pads 112a and 112b are mounted on the main board 130 by establishing an electrical connection to the external connection terminal 140. The electrical connection may be obtained by a soldering process.

In this example, because the external connection terminal 140 is soldered to the metal pads 112a and 112b formed on the side surface and the lower surface of the semiconductor package, a larger bonding area may be secured in comparison to an example in which the external connection terminal 140 is soldered only to a metal pad disposed on a lower surface of a semiconductor package. Thus, by providing the metal pads 112a and 112b on both a side surface and a lower surface of the semiconductor package, it is possible to obtain a larger bonding area, to prevent a drop or a thermal cycle, and to enhance reliability of solder joint.

FIG. 8 illustrates another example of a PCB according to the present description.

Referring to FIG. 8, the PCB according to this example includes an insulating layer 711, a circuit layer 712 including metal pads 713 and 712c exposed to both side surfaces and a lower surface of the insulating layer 711 and a metal layer 713 in a inner surface of a via hole penetrating through the insulating layer 711, and a solder resist layer 714 filling an opening exposing the metal pad 712c and the via hole formed in the insulating layer 711.

The metal pads 713 formed on both side surfaces of the insulating layer 711 are formed by cutting the via formed in the insulating layer 711, and the metal pad 712c exposed to the lower surface is provided to be the same as that of the circuit layer 712a formed on upper and lower surfaces of the insulting layer 711.

That is, since the metal pattern 713 of the side surface of the insulating layer 711 extends to the upper surface of the insulating layer 711, an area of the soldering pad may be increased.

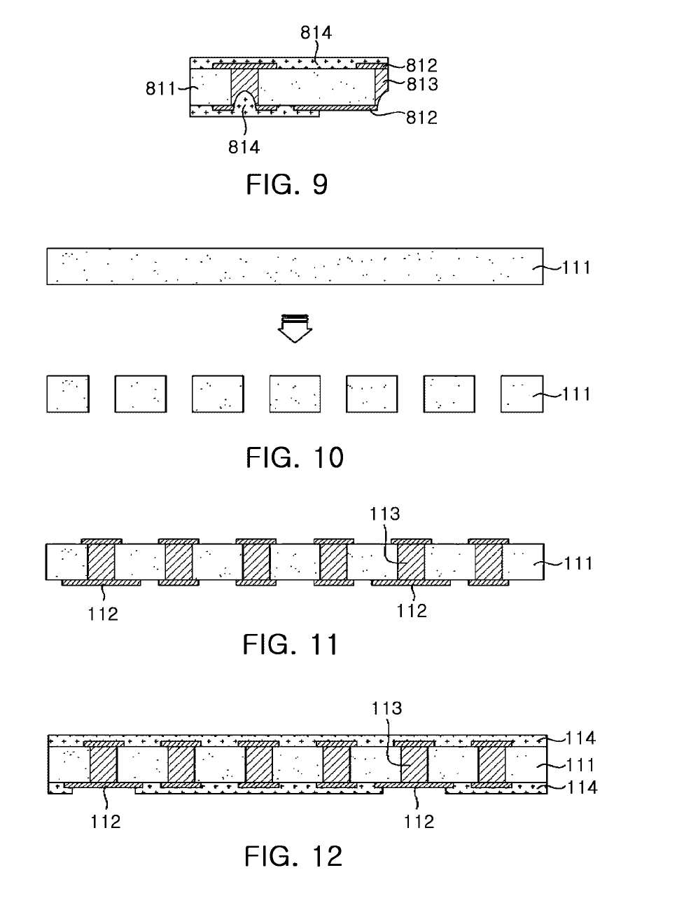

FIG. 9 illustrates yet another example of a PCB according to the present disclosure.

Referring to FIG. 9, the PCB according to the yet another example includes an insulating layer 811, a circuit layer 812 including metal pads 813 and 812 exposed to both side surfaces and a lower surface of the insulating layer 811, and a via penetrating through the insulating layer 811, and a solder resist layer 814 having an opening exposing the metal pad 812 and embedded in at least a portion of the via 813.

In this example, the via 813 is formed to be recessed to have a dimple shape, and the recessed portion of the via 813 is filled with the solder resist 814.

The metal pads 813 formed on both side surfaces of the insulating layer 811 are obtained by cutting the via having a dimple shape formed in the insulating layer 811, and the metal pad 812 exposed to the lower surface of the insulating layer 811 is formed to be the same as the circuit layer 812 formed on upper and lower surfaces of the insulating layer 811.

That is, an area of a soldering pad of the side surface metal pattern 813 of the insulating layer 811 may be secured to stably perform soldering to an external connection terminal.

### Method of Manufacturing PCB

Hereinafter, an example of a manufacturing method will be described in detail. Here, the aforementioned PCB of FIG. 1 will be referred, and thus, repeated descriptions may be omitted.

FIGS. 10 through 13 illustrate a sequential process of an example of a method for manufacturing a PCB according to the embodiment illustrated in FIG. 1.

Referring to FIG. 10, an insulating substrate (insulating layer) 111 is prepared, and vias vertically penetrating through the insulating substrate 111 are formed.

According to one example, the insulating substrate (insulating layer) 111 is formed of prepreg. Alternatively, the insulating substrate (insulating layer) 111 may be formed of a thermosetting insulating material, a ceramic, or an organic/inorganic composite material. The insulating substrate (insulating layer) 111 may be impregnated with glass fiber. In one example, the insulating layer 111 includes a polymer resin, or an epoxy-based insulating resin such as FR-4, bismaleimide triazine (BT), ajinomoto build-up film (ABF). Alternatively, the insulating layer 111 may include a polyimide-based resin, but the material of the insulating layer 111 is not limited thereto.

In one example, the via holes are formed in the insulating substrate (insulating layer) 111 by using a YAG laser or a CO₂ laser.

The insulating layer may be formed as built-up layers by stacking two or more layers.

Referring to FIG. 11, a circuit layer 112 including vias, dummy vias 113, and metal pad may be formed in the insulating layer 111.

The via holes formed in the insulating layer 111 may be filled with a metal to form the vias and the dummy vias.

Metal layers are formed on both surfaces of the insulating layer 111. For example, the metal layers may be formed to be thin using copper. The metal layers may be thin copper layers.

The metal layers are selectively removed to form a metal pad pattern and a circuit pattern. For example, the circuit pattern is formed using a subtractive method, an additive method using electroless copper plating and electro-copper plating, and a semi-additive process (SAP) method. That is, without being limited to the aforementioned process, a general circuit formation process known in the art may be applied by utilizing an etching process as a circuit method.

Thereafter, referring to FIG. 12, solder resist layers 114 having an opening exposing the metal pad 112 formed on the lower surface of the insulating layer 111 are formed. In this example, the metal pad 112 is a lower surface metal pad for solder bonding the package to an external connection terminal of a main board.

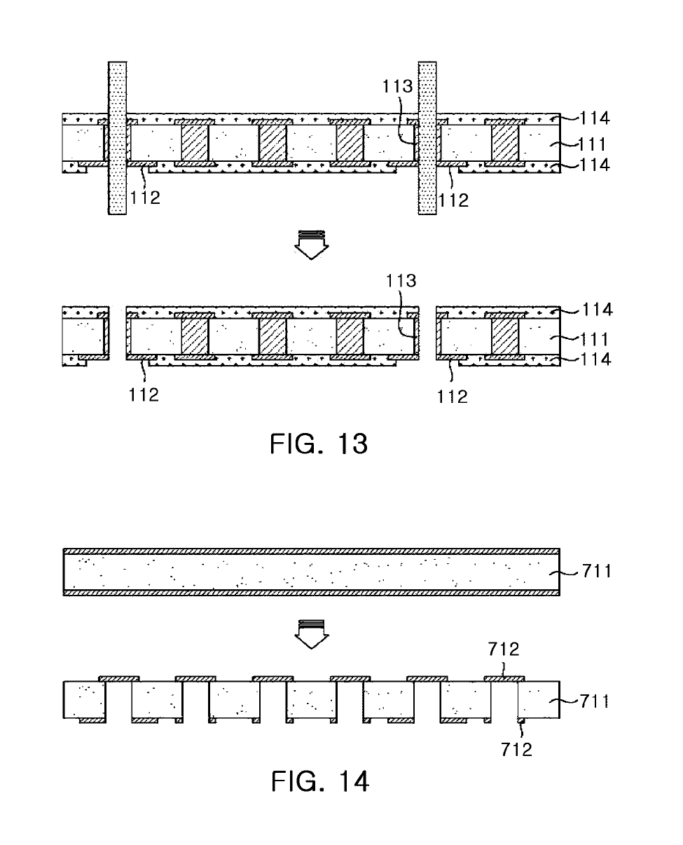

Thereafter, referring to FIG. 13, a metal side surface pad 112a of the insulating layer 111 is formed by cutting a central portion of the dummy via 113. In this example, the dummy via 113 is connected to the lower surface metal pad 112.

The cutting of the central portion of the dummy via is a process of cutting a plurality of units formed on the board into a single semiconductor package unit.

Thus, metal pads for soldering are formed on the side surfaces and the lower surface of the PCB formed as a single semiconductor package unit.

A semiconductor device is mounted on the insulating layer of the cut PCB, and the mounted semiconductor is molded so as to be fixed to complete a semiconductor package. The metal pads exposed to the side surfaces and the lower surface of the insulating layer are soldered to be bonded to the main board via an external connection terminal of the main board.

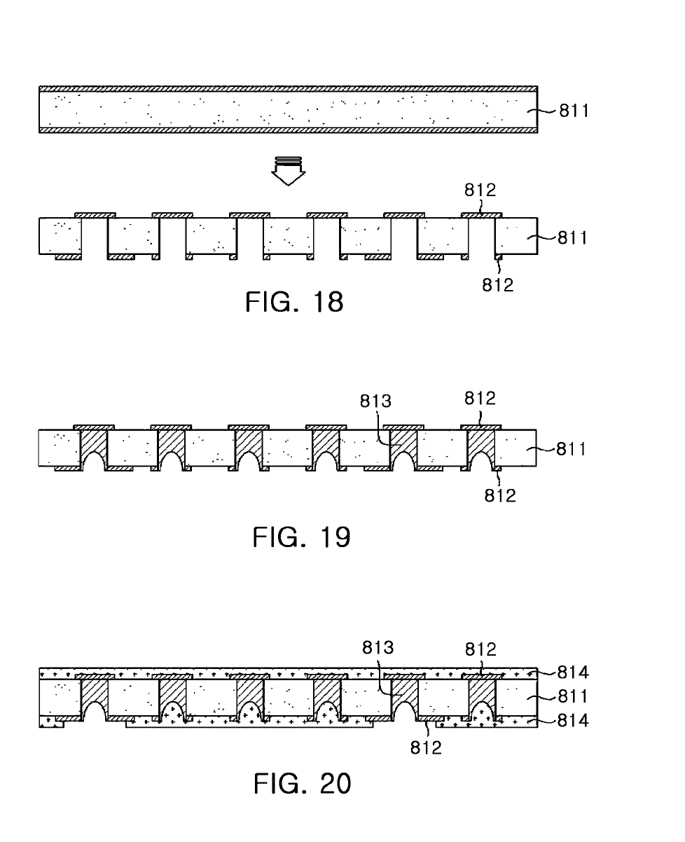

FIGS. 14 through 18 are views illustrating a sequential process of a method for manufacturing a PCB according to the second exemplary embodiment in the present disclosure.

Referring to FIG. 14, an insulating substrate (insulating layer) 711 with metal layers formed on both surfaces thereof is prepared, a circuit pattern is formed thereon, and via holes are formed in one direction therein.

The metal layers are selectively removed to form a metal pad pattern and a circuit pattern. In this example, the circuit pattern may be formed using a subtractive method, an additive method using electroless copper plating and electro-copper plating, and a semi-additive process (SAP) method. In another example, without being limited to the aforementioned process, a general circuit formation process known in the art may be applied by utilizing an etching process as a circuit forming method.

According to one example, the via holes are formed by using a YAG laser or a CO₂ laser such that the circuit pattern of one surface of the insulating substrate (insulating layer) 711 is not penetrated thereby. That is, the via holes are formed such that the circuit pattern formed on the upper surface of the insulating substrate (insulating layer) 711 are left.

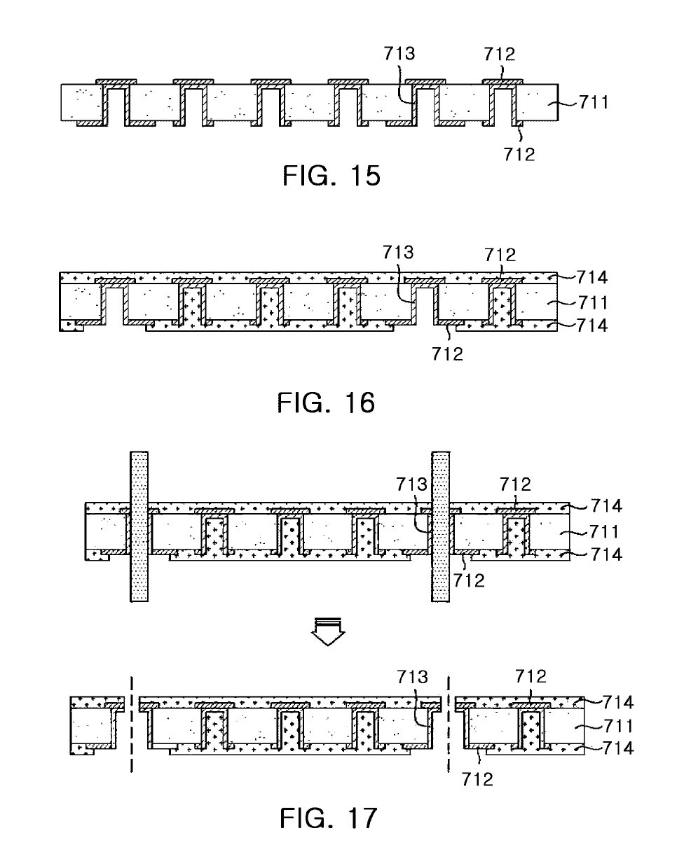

Referring to FIG. 15, an insulating layer 713 is formed on inner surfaces of the via and dummy via holes in the insulating layer 711. The metal layer 713 formed within the via is electrically connected to the metal layer 712 formed on the upper and lower surfaces of the insulating layer 711.

Thereafter, referring to FIG. 16, solder resist layers 714 having openings exposing the metal layer formed in the dummy via of the insulating layer 711 and the metal layer formed on the lower surface of the insulating layer 711 are formed. In this example, the solder resist layers 714 are provided on the upper and lower surfaces of the insulating layer 711 and fill the via holes on which the metal layer has been formed. The solder resist material corresponding to the dummy via is removed to expose the internal metal layer.

Thereafter, referring to FIG. 17, a central portion of the dummy via 713 is cut to form a metal pad 713 on a side surface and an upper surface of the insulating layer 711. The sewing of the central portion of the dummy via is a process of cutting a plurality of units formed on the board into a single semiconductor package unit.

Thus, metal pads for soldering are formed on the side surfaces and the lower surface of the PCB formed as a single semiconductor package unit.

FIGS. 19 through 21 illustrate a sequential process of an example of a method for manufacturing a PCB according to the embodiment illustrated in FIG. 9.

Referring to FIG. 19, an insulating substrate (insulating layer) 811 with metal layers formed on both surfaces thereof is prepared, a circuit pattern is formed thereon, and via holes are formed in one direction therein.

The metal layers are selectively removed to form a metal pad pattern and a circuit pattern. According to one example, the circuit pattern is formed using a subtractive method, an additive method using electroless copper plating and electro-copper plating, and a semi-additive process (SAP) method. In another example, without being limited to the aforementioned process, a general circuit formation process known in the art may be applied by utilizing an etching process as a circuit method.

In this example, the via holes may be formed by using a YAG laser or a CO₂ laser such that the circuit pattern of one surface of the insulating substrate (insulating layer) 811 is not penetrated thereby. That is, the via holes are formed such that the circuit pattern formed on the upper surface of the insulating substrate (insulating layer) 811 are left.

Referring to FIG. 20, the interior of the via hole and the dummy via hole of the insulating layer 811 are filled with a metal. In this example, the metal filling the interior of the via is formed to have a dimple shape. The dummy via 813 is electrically connected to the metal layers 812 formed on upper and lower surfaces of the insulating layer 811.

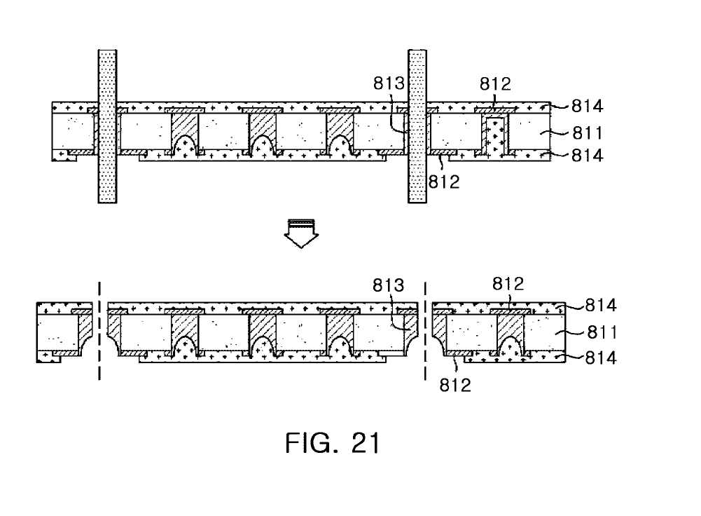

Thereafter, referring to FIG. 21, solder resist layers 814 having openings exposing the metal layer formed in the dummy via of the insulating layer 811 and the metal layer formed on the lower surface of the insulating layer 811 are formed. In this example, the solder resist layers 814 are provided on the upper and lower surfaces of the insulating layer 811 and fill the vias having the dimple shape. The solder resist material corresponding to the dummy via is removed to expose the internal metal layer.

Thereafter, referring to FIG. 21, a central portion of the dummy via 813 is cut to form a metal pad 813 on a side surface and an upper surface of the insulating layer 811. In this example, the cutting of the central portion of the dummy via is a process of cutting a plurality of units formed on the board into single semiconductor package units.

Metal pads for soldering are formed on the side surfaces and the lower surface of the PCB formed as a single semiconductor package unit.

Thus, since the external connection terminal is soldered to the metal pads 812 and 813 formed on the side surface and the lower surface of the semiconductor package to increase a bonding area, a drop or a thermal cycle may be prevented, enhancing reliability of solder joint.

An example of a printed circuit board described above includes a metal pad for soldering in order to increase a lifespan of a solder joint when a package is mounted thereon, thus enhancing product reliability.

Also, an example of a method for manufacturing a PCB described above involves forming a metal pad for soldering on a PCB to increase lifespan of a solder joint when a package is mounted thereon, thus enhancing product reliability.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board (PCB) comprising:
an insulating layer; and
a circuit layer comprising metal pads exposed on a side surface and a lower surface of the insulating layer.

2. The PCB of claim 1, wherein one of the metal pads covers substantially the entire side surface of the insulating layer.

3. The PCB of claim 1, wherein one of the metal pads covers a portion of the side surface of the insulating layer.

4. The PCB of claim 1, further comprising a solder resist layer having an opening exposing the metal pad.

5. The PCB of claim 1, wherein the PCB is a multilayer PCB.

6. The PCB of claim 4, wherein the PCB further comprises a via connecting an interlayer circuit layer, and the solder resist layer is embedded in at least a portion of the via.

7. A method of manufacturing a semiconductor package, the method comprising:
forming a circuit layer comprising a dummy via and a metal pad in an insulating layer;
forming a solder resist layer having an opening exposing the metal pad to both surfaces of the insulating layer; and
cutting through the dummy via to form a metal side surface pad of the insulating layer.

8. The method of claim 7, wherein the insulating layer is a built-up layer formed by stacking two or more layers.

9. The method of claim 7, wherein the forming of the circuit layer comprises
the metal pad being formed on a lower surface of the dummy via.

10. A method of manufacturing a semiconductor package, the method comprising:
obtaining a printed circuit board comprising an insulating layer and a metal side surface pad disposed on a side surface of the insulating layer; and
mounting a semiconductor device on the printed circuit board.

11. The method of claim 10, wherein the obtaining of the printed circuit board comprises:
forming a metal lower surface pad on a surface of an insulating layer and forming a dummy via that penetrates the insulating layer; and
cutting through the dummy via of the insulating layer to obtain the metal side surface pad on the side surface of the insulating layer.

12. The method of claim 11, wherein the metal side surface pad and the metal lower surface pad are formed adjacent to each other at a corner of the insulating layer.

13. A method of manufacturing a semiconductor package system, the method comprising:
manufacturing a semiconductor package according to the method of claim 1; and
electrically connecting the metal side surface pad of the semiconductor package with an external terminal of a main board by soldering.

14. The method of claim 13, wherein the electrically connecting of the metal pad to the external terminal comprises soldering both the metal lower surface pad and the metal side surface pad to the external terminal.
